(19) United States
(12) Patent Application Publication
(10) Pub. No.: US 2025/0236510 A1
(43) Pub. Date: Jul. 24, 2025

(54) HIERARCHICAL WAVY STRUCTURED SURFACES AND METHOD OF MAKING THEREOF

(71) Applicant: University of Massachusetts, Westborough, MA (US)

(72) Inventors: Tingyi Liu, Amherst, MA (US); Qingyang Sun, Amherst, MA (US)

(73) Assignee: University of Massachusetts, Westborough, MA (US)

(21) Appl. No.: 19/033,546

(22) Filed: Jan. 22, 2025

Related U.S. Application Data
(60) Provisional application No. 63/623,368, filed on Jan. 22, 2024.

(51) Int. Cl. B81C 1/00; B32B 3/30; B32B 27/28; B32B 37/10; B32B 38/00

(52) U.S. Cl. CPC B81C 1/00206; B32B 3/30; B32B 27/283; B32B 38/1875; B32B 37/1018; B32B 2307/73; B32B 2307/7375; B81C 2201/0194

(57) ABSTRACT

A versatile method to create hydrophobic 3-D surfaces with complex hierarchical microstructures that mimic the patterns found on springtail skin is disclosed. The method innovatively merges two fixed-spacing patterns at different scales to create patterns with varying spacing but does not require precise alignment. By utilizing localized stretching strain when gradually laminating a thin microstructured elastomer layer onto a wavy substrate, a pattern is created. To demonstrate this new fabrication process, we laminated a thin polydimethylsiloxane (PDMS) film having a plurality of microstructures thereon, on a wavy PDMS substrate with millimeter-scale inverted pyramidal holes. This resulted in hierarchical surface microstructures that display varying spacings along the peaks and the valleys of the wavy substrate.

### CROSS-REFERENCE TO RELATED APPLICATIONS

This patent document claims priority to earlier filed U.S. Provisional Patent Application Ser. No. 63/623,368, filed on Jan. 22, 2024, the entire contents of which are incorporated herein by reference.

### STATEMENT REGARDING FEDERALLY SPONSORED RESEARCH OR DEVELOPMENT

This invention was made with government support under National Science Foundation CMMI-AM Program Grant #2225964 and National Institutes of Health Trailblazer Award 1R21EB033599-01A1. The government has certain rights in the invention.

### BACKGROUND OF THE INVENTION

### 1. Field of the Invention

The present patent document is directed generally to hierarchical structures having hydrophobic properties, and more particularly to hierarchical wavy structured surfaces and methods of making thereof.

### 2. Background of the Related Art

Referring to FIGS. 1A-1C, 2A, 2B, 3A-3C, Hierarchical structures are commonly observed in nature and often play a crucial role in imparting and maintaining hydrophobic properties to various organisms/insects such as springtails 10 [1]-[3]. Based on recent anatomy studies of the springtails 10, its hydrophobicity is primarily attributed to the unique structure of the skin, which exhibits a hierarchical arrangement of granules 12 distributed across the surface [1]. As a type of moisture-loving insect found in soil, springtails 10 need to maintain water-repellent properties at high humidity (for example, they often display positive hydrotaxis, which is the movement towards moisture) and against mechanical shear stress (for example, when burrowing through loose soil, decaying wood, or under the bark of trees). Therefore, some springtails' skin displays a unique arrangement of surface structures that are not observed on other species: At the microscale, the skin shows a wavy or ridged pattern. At the sub-microscale, the granules 12 are predominantly aggregated on the peaks 14 and sparsely on the valleys 16.

Inspired by the springtail skin, previous works [4]-[6] have employed pre-stretching methods to induce hierarchical wrinkles on deformable surfaces. These methods need exact control over how much the material is stretched, which is hard to achieve consistently in different manufacturing settings. In other efforts, alignment techniques [7], [8] were explored to mimic hierarchical surfaces, however, the accuracy requirements limit the scalability and practical implementation. To address this, self-alignment methods involving multi-steps of deposition and etching on masked patterns were developed [9]-[11]. However, these methods require a series of timed-etching processes, limiting their upscaling capability. Additionally, these techniques are limited to creating either periodic or semi-random patterns of surface roughness. Achieving surface roughness with deliberately varied spacing, known as controlled gradient spacing, has remained elusive. This is due to the complexities in designing appropriate masks or the absence of suitable fabrication methods.

Accordingly, there is a need in the prior art for improved methods of manufacturing hierarchical structures.

### SUMMARY OF THE INVENTION

This patent document discloses a novel method that offers a simplified fabrication process to realize hierarchical structures with controlled gradient spacing yet using only two fixed-spacing patterns. The hierarchical structures described herein to create mechanically robust super-repellent surfaces. Two scales of patterns: a wavy pattern at the millimeter-scale (or micrometer scale) and granule aggregation on the peaks at the sub-millimeter scale (or sub-micrometer scale). Different from existing super-repellent surfaces based on hierarchical structures with uniform/random solid fractions, this method specifies that a gradient of solid fractions is required to enable liquid repellency, mechanical robustness, and moisture resistance. The methods and structures described herein have a variety of practical uses to make super-repellent articles, including clothes, laminable films that can adhere to any surface (e.g., phone screen protectors with omni-liquid repellency, fingerprint-free films, self-cleaning windows, solar panel coating, etc.), anti-biofouling substrate, coating, and the like.

### BRIEF DESCRIPTION OF THE DRAWINGS

These and other features, aspects, and advantages of the present invention will become better understood with reference to the following description, appended claims, and accompanying drawings where:

FIG. 1A shows an image of a natural springtail, Kalaphorura burmeisteri;

FIG. 1B is a SEM image of the skin of Inset 1B of FIG. 1A at magnification, showing the distribution of aggregated and spare granules;

FIG. 1C is a SEM image of the skin of Inset 1C of FIG. 1B at further magnification, showing the distribution of aggregated and sparse granules;

FIG. 2A shows an image of Tetrodontophora bielanensis;

FIG. 2B is a SEM image of Inset 2B of FIG. 2A of the skin of Tetrodontophora bielanensis, showing hierarchical structures with varying solid fraction;

FIG. 3A shows another natural springtail, Neanurinae, and SEM of the skin;

FIG. 3B is a SEM image of Inset 3B of FIG. 3A of the skin of Neanurinae at magnification, showing the distribution of aggregated and sparse granules;

FIG. 3C is a SEM image of Inset 3C of FIG. 3B of the skin of Neanurinae at a further magnification, showing the distribution of aggregated and sparse granules;

FIG. 4A shows a schematic illustration of a first method of forming a hierarchical wavy structured surface, where a PDMS wavy structure is prepared by demolding from a 3D printed mold, while a thin layer of microstructures is created by spin coating PDMS on a microstructured mold, where two surfaces are brought into contact with pressure after plasma activation;

FIG. 4B shows a schematic illustration of a second method of forming a hierarchical wavy structured surface, where and a free-standing thin film is positioned on the PDMS wavy structure with the cavities sealed, and both surfaces are treated with oxygen plasma, where upon applying vacuum, the thin film laminates onto the surface;

FIG. 4C shows a schematic illustration of a hierarchical wavy structured surface prepared using the methods shown in either FIG. 4A or FIG. 4B;

FIG. 5 shows the schematic of the dynamic deformation of overhanging thin film during the application of a vacuum, where the thin film gradually adhering to underlying wavy structures, leading to non-uniform stretching and bonding between the film and the structures, resulting in varying spacing between the surface structures along the peaks and valleys of the wavy base;

FIG. 6 shows the experimental validation of the process depicted in FIGS. 4C and 5, where at Step A in the initial state, the pillar and pitch remain undeformed, with an initial solid fraction (fₛ) of 29%; at Step B, upon applying vacuum, both the pillar and pitch expand, leading to a decrease in the fₛ, which reaches 19%; and at Step C in the final state, the pillar undergoes minimal expansion, while the pitch expands further, where consequently, the fₛ decreases to 11%;

FIG. 7 shows a chart of the result of the laminated sample along with the characterization of the fₛ across the peak-slope-valley area, exhibiting a dense distribution of microfeatures on the peak and an increasingly sparser distribution along the slope down to the valley, generating a gradient in spacing (i.e., solid fraction);

FIG. 8 shows an image of an experimental embodiment the density of microfeatures, fₛ, across the peak-slope-valley are characterized at 29%, 17%, and 6%, respectively;

FIG. 9A shows an image of an experimental embodiment of a hierarchical wavy structured surface made in accordance with the methods disclosed herein; and

FIG. 9B shows an image of another experimental embodiment of a hierarchical wavy structured surface made in accordance with the methods disclosed herein.

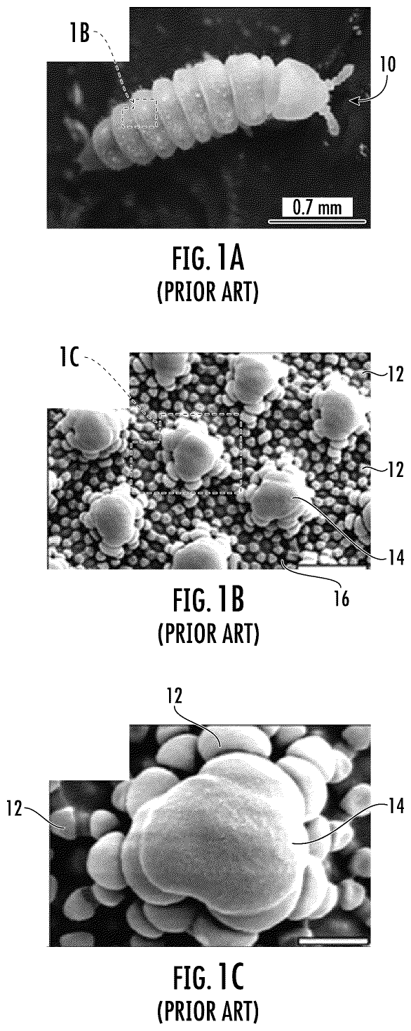

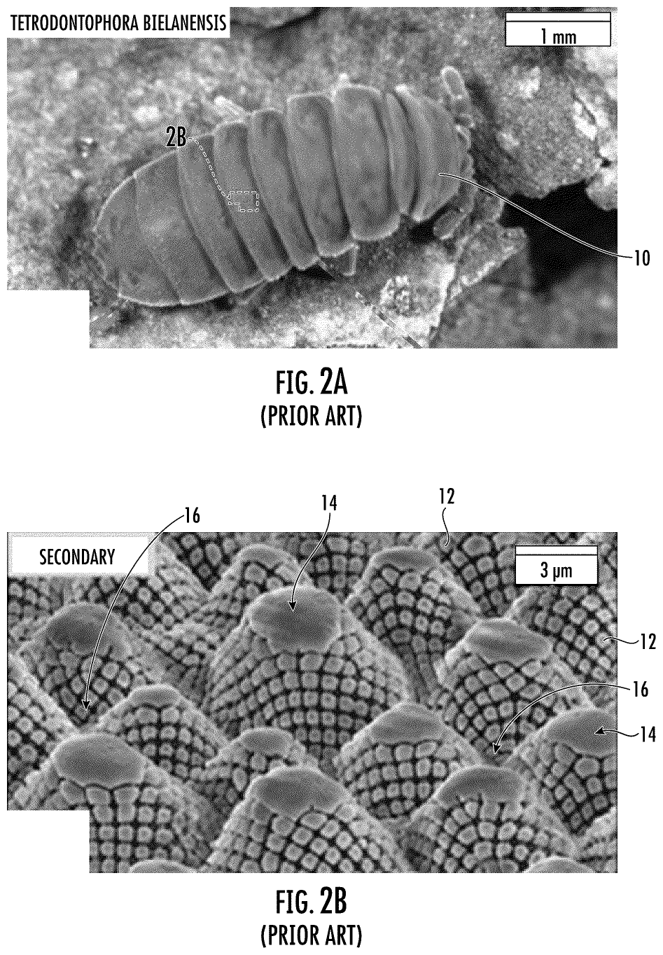

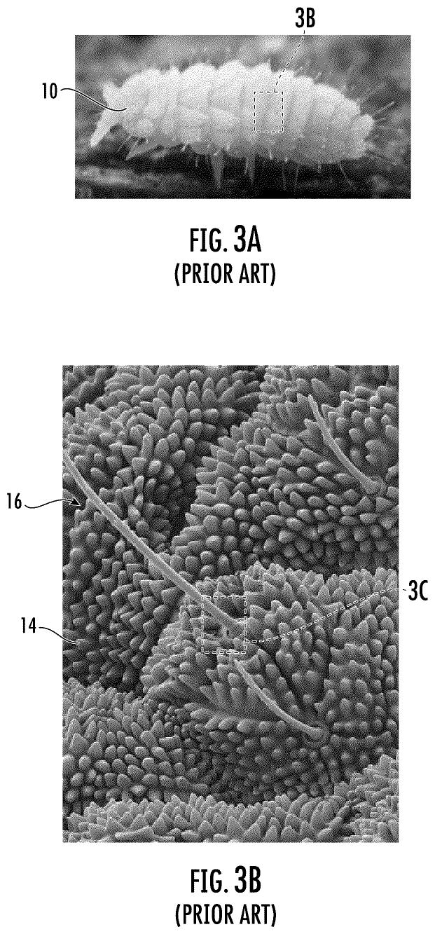

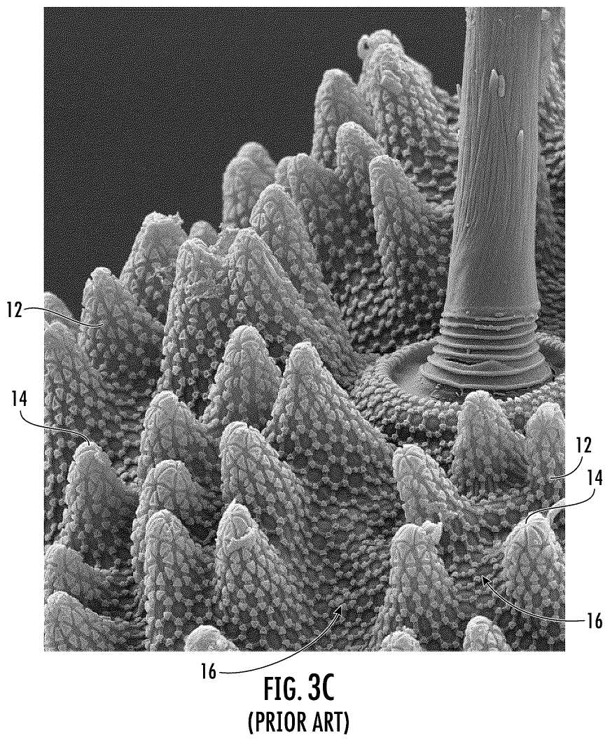

### DESCRIPTION OF A PREFERRED EMBODIMENT

A novel method that offers a simplified fabrication process to realize hierarchical structures with controlled gradient spacing yet using only two fixed-spacing patterns is disclosed. We will first explain our design and its working mechanism. Second, we will present a scalable MEMS fabrication process to realize our design. Third, we will experimentally verify the working mechanism to fabricate hierarchical microstructures with gradient spacing with direct visualization using high-resolution microscopic imaging. Finally, we will demonstrate the fabricated 3D hierarchical surface patterns with varying spacing along the peaks and valleys of the wavy substrate.

### Design

Our approach to designing hierarchical structures 100 with varying spacing is similar to but different from the pre-stretch method that utilizes strain to generate 3D structures. We employed a pre-defined wavy structure 102 at the millimeter (or micrometer) scale as the substrate and a thin film 104 with surface structures 106 at the sub-millimeter (or sub-micrometer) scale as the lamination layer. The thin film 104 was laminated and bonded onto the wavy structure 102. Initially, the structured thin film 104 contacted the peak of the wavy structure 102, maintaining its structure density as a free-standing thin film. As the thin film 104 was laminated, it was gradually stretched, resulting in a gradient density of structures 106 across the thin film 104. By controlling the dimensions of the wavy structure 102 and microstructures 106, we can achieve a hierarchical structure 100 with a desirable gradient.

### Methods

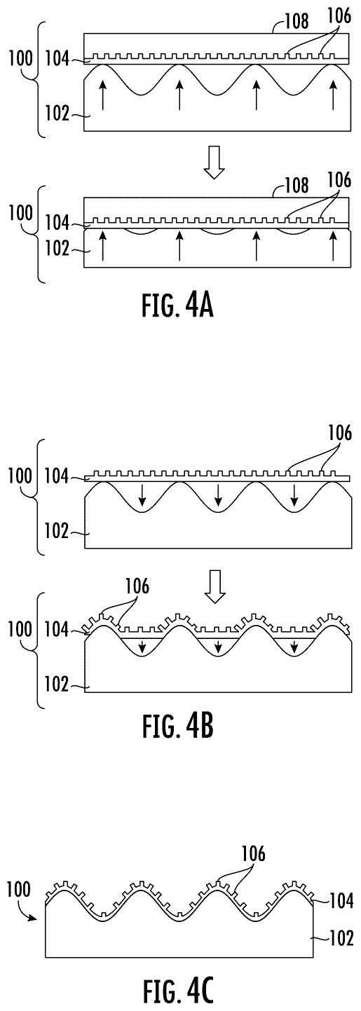

An example of the fabrication process flow to realize our design is shown in FIG. 4A. A wavy mold 108 with millimeter features was first 3D-printed (Stratasys Objet Connex350) using VeroWhite (rigid) as the material and coat hydrophobic with a silane (Trichloro(1H,1H,2H,2H-perfluorooctyl)silane) to facilitate demolding. We adopted the general procedure of soft lithography to fabricate the PDMS (Sylgard 184, with a common 10:1 ratio between the base and the curing agent) wavy structure from a 3D-printed wavy (e.g., sinusoidal) mold with a height of 1 mm and pitch of 2 mm. The microstructured thin film is prepared by spin-coating PDMS on a SU-8 or Si mold (an array of 60 μm micro-holes with a 100 μm pitch) at 3000 rpm for 3 minutes. The demolded PDMS resulted in interconnected micropillars with a diameter of 60 μm and a height of 20 μm. Both the PDMS wavy substrate and PDMS thin film were first exposed to an oxygen plasma (PETS, 500 mTorr, 80 Watts, 30 sec) and then brought into contact and compressed to enable the thin film lamination. The hierarchical surface is formed after fully bonding (best seen in FIG. 4C).

Referring to FIG. 4B, another example of the fabrication process using a vacuum pressure to laminate the thin film 104 to the wavy structure 102 is shown. A microfluidic vacuum system (PreciGenome iFlow™ Pressure/Flow Controller) was adopted for the thin film lamination process with gradually increased stretching to the thin film as it laminated to the wavy structure. Specifically, the vacuum was applied to one specific well unit, causing the overhanging thin film 104 to stretch and laminate on the millimeter-scale wavy structures 102. The escalating pressure levels were recorded and a camera with macro-lens (Canon EOS 6D Mark II with Canon MP-E lens) simultaneously captured the process of the microstructured thin film 104 laminated on the wavy substrate 102. The dimensions of the size of the microstructures 106 (e.g., pillars) and the spacing between them were measured from the captured images.

### Experiments and Results

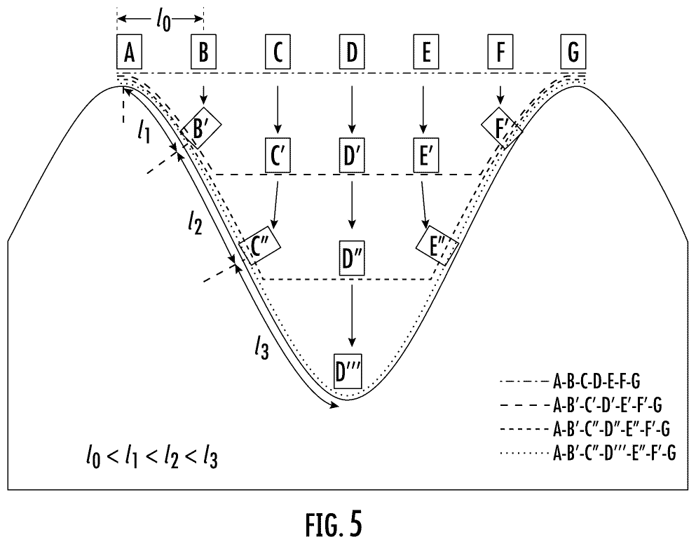

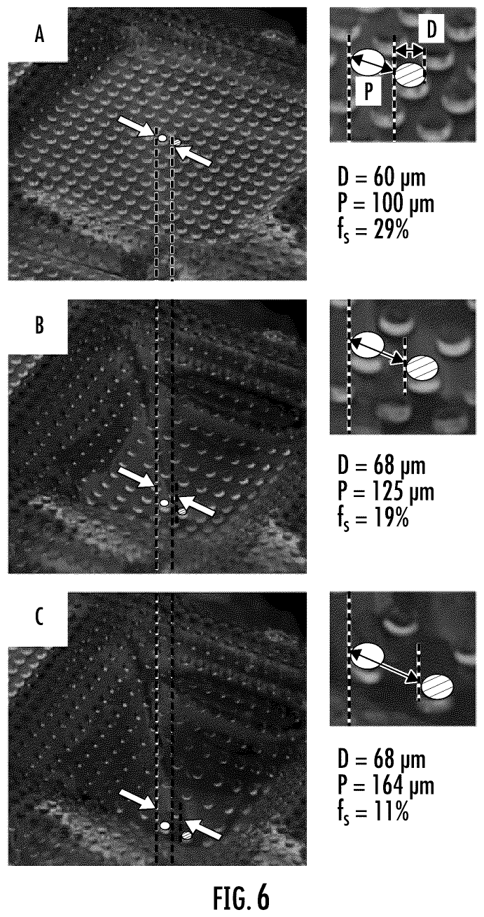

The visualization of the lamination process of a thin film 104 with micropillars 106 on a wavy substrate 102 with an inverted pyramidal hole (i.e. the valley between the peaks of the wavy surface) is shown in FIGS. 5 and 6. It can be observed that upon applying a vacuum, the overhanging thin film 104 undergoes continuous deformation where the boundary regions are laminated and conform to the wavy sidewall through continuous stretching.

As shown in FIG. 5, the structures on the thin film, labeled A through G, are evenly spaced at the top with the length denoted as l₀. However, as the film conforms to the wavy structures, it must stretch to accommodate the longer path of the wavy contour. This stretching alters the spacing between the microstructures. When points B and F adhere to the wavy structure, the thin film's sequence changes to A-B′-C′-D′-E′-F′-G. Subsequently, as points C and E adhere, the sequence becomes A-B′-C″-D″-E″-F′-G. Finally, when point D adheres, the sequence is A-B′-C″-D′″-E″-F′-G. The distances between adjacent microstructures, such as A-B′, B′-C″, and C″-D′″, are denoted as l₁, l₂, and l₃, respectively. These distances exhibit an increasing trend (l₁<l₂<l₃), indicating a gradient in the spacing along the thin film. This gradient reflects the varying degree of stretching that the thin film undergoes as it conforms to the wavy underlying structure.

Referring to FIG. 6, the progression of spacing between the microstructures as the thin film stretches is shown at various points in the lamination process. Initially, the units show a diameter of 60 μm and pitch of 100 μm in FIG. 6 at Step A. Upon medium vacuum (˜−0.5 psi), the pitch was expanded to 125 μm, as shown in FIG. 6 at Step B. In the final stage (˜−0.9 psi), the pitch expands further to 164 μm, as depicted in FIG. 6 at Step C. It is worth noting that the microstructures also experience some expansion from 60 μm to 68 μm, although the extent of deformation is much smaller compared to the spacing between the microstructures.

The above findings are consistent with the designs shown in FIG. 4C. This can be understood as follows: as the lamination process progresses along the wavy substrate, the strain on the microstructured thin film increases. This increase in strain is due to the growing ratio of the actual area to the projected area of the film, which in turn leads to a gradient spacing in the hierarchical patterns.

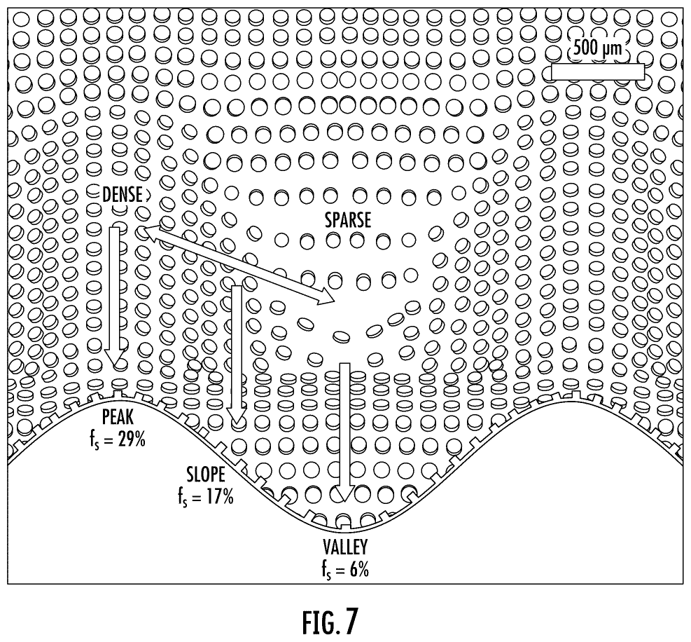

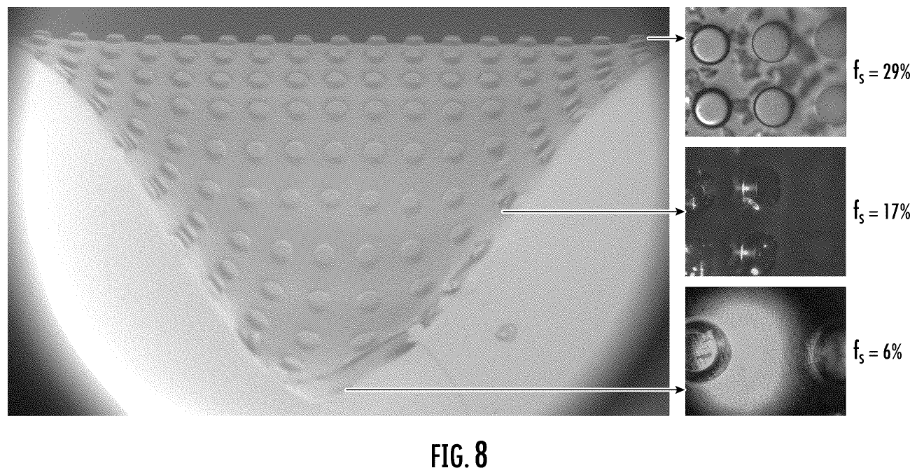

Based on the results of the visualization of the lamination process on one unit/well, we fabricated the sample using the compression method over large areas. FIG. 7 illustrates the resulting sample, which exhibits a dense distribution of features on the peak and sparse features along the slope and valley, thereby creating a gradient along the slope. Using this method, we were able to achieve a surface with a solid fraction that is four times smaller than its initial solid fraction, from 29% to 6%. As shown in FIG. 8, the image shows the spacing between the microstructures fₛ at 29%, 17%, and 6%.

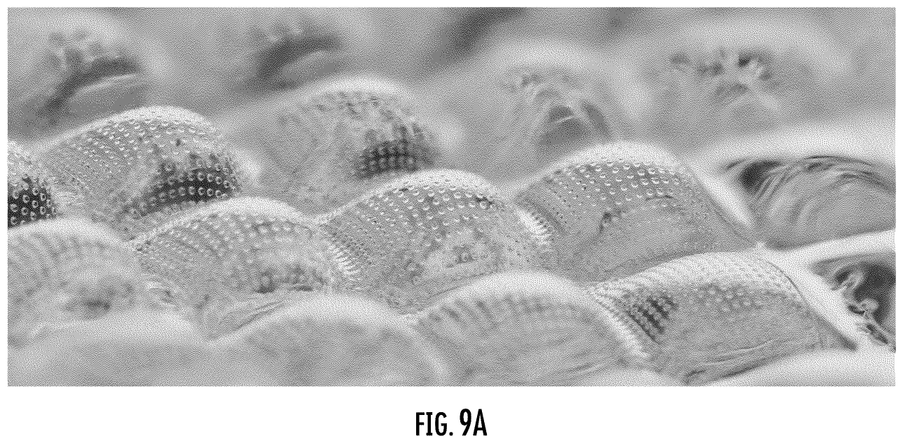

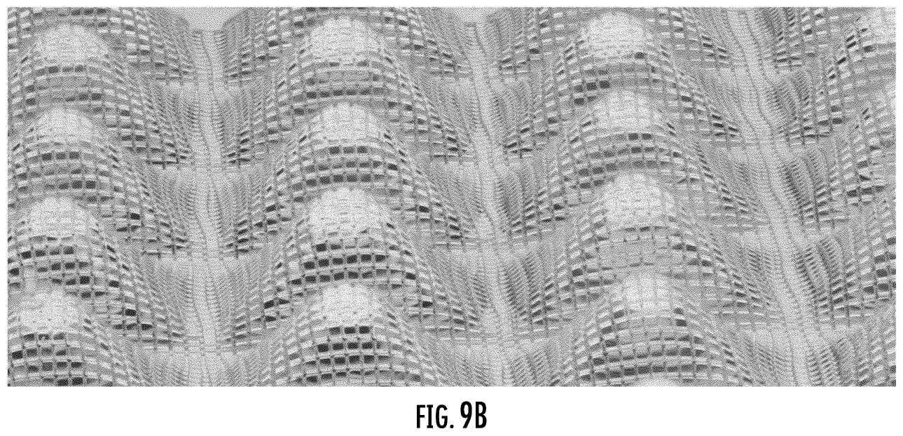

Referring to FIG. 9A, an alternative embodiment of a hierarchical wavy structured surface made in accordance with the methods disclosed herein, is shown generally. In this embodiment, the wavy surface has a sinusoidal shape with circular micropillars with a moderate solid fraction at the peaks (˜30%) and a tiny solid fraction in the valleys (˜6%).

Referring to FIG. 9B, another alternative embodiment of a hierarchical wavy structured surface made in accordance with the methods disclosed herein, is shown generally. In this embodiment, the wavy surface has a pentahedral shape (i.e. pyramidal) with square micropillars with a high solid fraction at the peaks (˜72%) and a moderate solid fraction in the valleys (˜38%).

### CONCLUSION

A simple and effective method for fabricating 3-D surfaces with hierarchical microstructures that mimic the varying spacing patterns observed on springtail skin is disclosed. The localized gradual stretching method was validated using the macro visualization, and the fabricated sample confirmed the design mechanism, resulting in a uniform fourfold difference in spacing on a single sample. This alignment-free method offers new scientific insights into the complex 3D hierarchical structures on natural surfaces with special wetting properties. To our best knowledge, this is the first report to generate controllable micro-patterns with a gradient spacing from fixed-spacing patterns. This novel process overcomes one of the major challenges in producing bio-inspired patterns with diverse variations for studies of biomimicry and biomutualism.

It would be appreciated by those skilled in the art that various changes and modifications (such as materials, types of wavy structures, types of surface structures, lamination techniques, etc.) can be made to the illustrated embodiments without departing from the spirit of the present invention. All such modifications and changes are intended to be within the scope of the present invention except as limited by the scope of the appended claims.

### REFERENCES

All references incorporated herein by reference in their entirety.
[1] R. Helbig, J. Nickerl, C. Neinhuis, and C. Werner, “Smart Skin Patterns Protect Springtails,” PLoS One, vol. 6, p. e25105, September 2011, doi: 10.1371/journal.pone.0025105.
[2] Z. Lian, J. Xu, Z. Wang, and H. Yu, “Biomimetic Superlyophobic Metallic Surfaces: Focusing on Their Fabrication and Applications,” J. Bionic Eng., vol. 17, no. 1, pp. 1-33, 2020, doi: 10.1007/s42235-020-0002-y.
[3] R. Hensel, R. Helbig, S. Aland, A. Voigt, C. Neinhuis, and C. Werner, “Tunable nano-replication to explore the omniphobic characteristics of springtail skin,” NPG Asia Mater., vol. 5, no. 2, pp. e37-e37, 2013, doi: 10.1038/am.2012.66.
[4] C. Cao, H. F. Chan, J. Zang, K. W. Leong, and X. Zhao, “Harnessing Localized Ridges for High-Aspect-Ratio Hierarchical Patterns with Dynamic Tunability and Multifunctionality,” Adv. Mater., vol. 26, no. 11, pp. 1763-1770, March 2014, doi: https://doi.org/10.1002/adma.201304589.
[5] Y. Wang, Q. Sun, and J. Xiao, “Simultaneous formation of multiscale hierarchical surface morphologies through sequential wrinkling and folding,” Appl. Phys. Lett., vol. 112, no. 8, p. 81602, February 2018, doi: 10.1063/1.5020177.
[6] Z. Li, Y. Zhai, Y. Wang, G. M. Wendland, X. Yin, and J. Xiao, “Harnessing Surface Wrinkling-Cracking Patterns for Tunable Optical Transmittance,” Adv. Opt. Mater., vol. 5, no. 19, p. 1700425, October 2017, doi: https://doi.org/10.1002/adom.201700425.
[7] S. M. Kang and J. S. Choi, “Selective Liquid Sliding Surfaces with Springtail-Inspired Concave Mushroom-Like Micropillar Arrays,” Small, vol. 16, no. 3, p. 1904612, January 2020, doi: https://doi.org/10.1002/smll.201904612.
[8] V. Rontu, V. Jokinen, and S. Franssila, “Scalable Superomniphobic Surfaces,” J. Microelectromechanical Syst., vol. 29, no. 1, pp. 54-61, 2020, doi: 10.1109/JMEMS.2019.2950769.
[9] T. “Leo” Liu and C.-J. “CJ” Kim, “Turning a surface superrepellent even to completely wetting liquids,” Science (80-.), vol. 346, no. 6213, pp. 1096-1100, November 2014, doi: 10.1126/science.1254787.
[10] G.-T. Yun et al., “Springtail-inspired superomniphobic surface with extreme pressure resistance,” Sci. Adv., vol. 4, no. 8, p. eaat4978, November 2018, doi: 10.1126/sciadv.aat4978.
[11] S. Dong et al., “Springtail-Inspired Superamphiphobic Ordered Nanohoodoo Arrays with Quasi-Doubly Reentrant Structures,” Small, vol. 16, no. 19, p. 2000779, May 2020, doi: https://doi.org/10.1002/smll.202000779.

What is claimed is:

1. A method of forming a hydrophobic surface, comprising:
providing a substrate having an uneven surface; and
laminating a microstructured film comprising a plurality of microstructures over the uneven surface.

2. The method of claim 1, further comprising forming the microstructured film with a plurality of microstructures thereon.

3. The method of claim 2, wherein the step of forming the microstructured film comprises forming the microstructured film through coating a polymer on a mold.

4. The method of claim 2, wherein the plurality of microstructures comprises micropillars, micro-gratings, and micro-holes, and combinations thereof.

5. The method of claim 1, wherein the step of laminating the microstructured film over the uneven surface comprises stretching the microstructured film over the uneven surface.

6. The method of claim 1, wherein the step of laminating the microstructured film over the uneven surface comprises applying a pressure difference between the microstructured film and the even surface.

7. The method of claim 1, wherein the step of laminating the microstructured film over the uneven surface comprises compressing the microstructured film against the uneven surface.

8. The method of claim 1, wherein the uneven surface of the substrate comprises a wavy surface.

9. The method of claim 8, wherein the wavy surface of the substrate comprises a sinusoidal surface.

10. The method of claim 1, wherein the wavy surface of the substrate is formed having a height of 3 mm or below and pitch of 5 mm or below.

11. A hydrophobic surface, comprising:
a substrate having an uneven surface; and
a microstructured film comprising a plurality of microstructures laminated over the uneven surface.

12. The product of claim 11, wherein the microstructured film comprises a plurality of microstructures thereon.

13. The product of claim 12, wherein microstructured film comprises a polymer layer.

14. The product of claim 12, wherein the plurality of microstructures comprises micropillars with a diameter of 600 μm or below and a height of 200 μm or below.

15. The product of claim 11, wherein the microstructured film is stretched over the uneven surface.

16. The product of claim 11, wherein the microstructured film is laminated to the uneven surface of the substrate by applying a vacuum to the microstructured film.

17. The product of claim 11, wherein the microstructured film is laminated to the uneven surface by compressing the microstructured film against the uneven surface.

18. The product of claim 11, wherein the uneven surface of the substrate comprises a wavy surface.

19. The product of claim 18, wherein the wavy surface of the substrate comprises a sinusoidal surface.

20. The product of claim 11, wherein the wavy surface of the substrate is formed having a height of 3 mm or less and pitch of 5 mm or less.
